(19) United States
(12) Patent Application Publication
(10) Pub. No.: US 2022/0077142 A1
(43) Pub. Date: Mar. 10, 2022

(54) Method of Packaging a Rectifying Device and a Rectifying Device

(71) Applicant: Robert Bosch (Australia) Pty. Ltd., Clayton (AU)

(72) Inventors: Vemal Raja Manikam, Melbourne (AU); Damir Kljukijevic, Melbourne (AU)

(21) Appl. No.: 17/351,553

(22) Filed: Jun. 18, 2021

(30) Foreign Application Priority Data
Sep. 7, 2020 (AU) 2020903195

(51) Int. Cl. H01L 27/06; H01L 23/31; H01L 23/532; H01L 23/498; H01L 23/00

(52) U.S. Cl. CPC H01L 27/0629; H01L 23/3114; H01L 24/14; H01L 23/49811; H01L 23/53228

(57) ABSTRACT

A rectifying device includes a semiconductor die having first and second opposing surfaces and a first terminal and a second terminal. A power transistor has a source terminal connected to one of the first terminal or the second terminal of the rectifying device. A drain terminal is connected to the other one of the first terminal or the second terminal of the rectifying device and a gate. A gate control circuit is operable to control a gate voltage at the gate of the power transistor based on at least one parameter relating to at least one of a voltage and a current between the first terminal and the second terminal. A capacitor structure is provided wherein the power transistor, the gate control circuit and the capacitor structure are arranged in the semiconductor die forming a monolithic structure and the first and second opposing surfaces are at least in part metallised.

### CROSS-REFERENCE TO RELATED APPLICATIONS

This application claims priority to Australian Patent Application 2020903195, filed Sep. 7, 2020, the content of which is hereby incorporated by reference.

### TECHNICAL FIELD

This invention relates to semiconductors and, more particularly, to semiconductor structures and methods of using the same.

### BACKGROUND OF INVENTION

Rectifier diodes are widely used semiconductor devices. A rectifier diode is generally a two-lead semiconductor that allows current to pass in only one direction. They are often formed by joining together n-type and p-type semiconductor materials. Rectifier diodes are a vital component in power supplies, including alternators for vehicles, where they are used to convert alternating-current (AC) voltage to direct-current (DC) voltage.

In known alternators for vehicles, the full wave rectifier associated with the alternator can take up a substantial portion of the alternator (rectifier diodes are often packaged and then assembled on a rectifier plate, which forms part of the assembly of an alternator). This is both because of the structure of the components of the rectifiers and the need for having sufficiently large cooling surfaces. Cooling is a sufficiently important problem in vehicle alternators (and other power supplies) because the electrical and mechanical performance of rectifier diodes may degrade with heat by weakening delicate solder joints over time through thermal cycling and the like.

A typical prior art rectifier makes use of individually mounted and packaged rectifier diodes which are then wired to form the full wave rectifier. A typical mounting for each diode is a “can” which is a generally cup-shaped metal housing where a semiconductor diode chip and other components are soldered to external connections. The open end of the can is sealed so that the external connection extends out of the can, this external connection is often referred to as a “head wire” and can be prone to mechanical stress and thermomechanical loading which may decrease the thermal and electrical conductivity of connections and solder joint. There is internal space in the can to allow for a certain amount of expansion and contraction of the head wire.

It would be desirable to provide a rectifier diode which ameliorates or at least alleviates one or more of the above problems or to provide an alternative.

It would also be desirable to provide a rectifier diode that ameliorates or overcomes one or more disadvantages or inconvenience of known rectifying devices.

It would be also desirable to provide a simple monolithic rectifier structure which is easily fabricated, readily cooled and with strong solder joints.

A reference herein to a patent document or other matter which is given as prior art is not to be taken as an admission or a suggestion that the document or matter was known or that the information it contains was part of the common general knowledge as at the priority date of any of the claims.

### SUMMARY OF INVENTION

According to an aspect of the present invention, there is provided a rectifying device, comprising: a semiconductor die having first and second opposing surfaces; a first terminal and a second terminal; a power transistor having a source terminal connected to one of the first terminal or the second terminal of the rectifying device, a drain terminal connected to the other one of the first terminal or the second terminal of the rectifying device and a gate; a gate control circuit operable to control a gate voltage at the gate of the power transistor based on at least one parameter relating to at least one of a voltage and a current between the first terminal and the second terminal; and a capacitor structure, wherein the power transistor, the gate control circuit and the capacitor structure are arranged in the semiconductor die forming a monolithic structure and the first and second opposing surfaces are at least in part metallised. Advantageously, a monolithic arrangement may lead to simplified construction and reduced costs, for example.

In one or more embodiments, at least one of the first and second opposing surfaces is a solderable surface. The solderable surface may be a connection site configured to receive an external connection thereon and form a portion of a top or bottom surface of the semiconductor die.

In one or more embodiments, the first and second opposing surfaces is a copper (Cu) surface. The Cu surface may include a nickel (Ni) diffusion barrier deposited on at least part of the Cu surface for reducing the formation of intermetallics upon the application of solder. Advantageously, in this particular form of the invention the formation of intermetallics that may take place during reflow when the tin (Sn) in solder reacts with the copper substrate or layer may be reduced. In Sn-rich solders on a Cu substrate, Cu6Sn5 (η) or Cu3Sn (ε) intermetallic layers may be formed at the solder/substrate interface leading to eventual dewetting, which may result in solder joint failure (because interfacial intermetallic compound layers are prone to crack initiation and failure and other degraded mechanical properties).

In one or more embodiments, at least one of the first and second opposing surfaces is selected from the group consisting of: Ag, Au, Al, or their alloys.

In one or more embodiments, the Cu surface may further include a metallic mesh disposed thereon for reducing the formation of intermetallics upon the application of solder. In other implementations, the mesh may comprise a high melting point nonmetallic material such as polymer having high thermal stability. Advantageously, the integration of a mesh may also stabilise the solder against mechanical and thermomechanical loading and to increase the thermal conductivity of the joint. Stabilising the solder can also reduce a tilted head wire in manufacture and avoid the formation of “solder wedge”. Additionally, solder creep may be slowed, thereby enhancing wetting.

In one or more embodiments, the Cu surface may be textured for preventing the propagation of cracks that may form in intermetallics and solder upon the application of solder. Advantageously, a textured or rough surface may improve the mechanical properties of the solder joint due to the decreased resistance to shear along the interface. The texturing may be achieved by cold rolling, chemical etching, deposition of copper nanoparticles, and the like.

In one or more embodiments, the Cu surface may include a plurality of structures patterned for controlling solder flow. The plurality of structures may include metallic or polymer bumps disposed on the Cu surface. The structures may be dimensioned to be of similar height to a solder bondline and arranged in a grid-like pattern or may be randomly or pseudo-randomly disposed on the Cu surface.

In one or more embodiments, the semiconductor die may be adapted to be packed in a two terminal press fit package having a socket and a head wire. Two terminal press fit packages are commonly used in vehicle alternators.

In one or more embodiments, the semiconductor die is soldered between the socket and the head wire.

In one or more embodiments, the semiconductor die may be soldered between the socket and the head wire with a solder containing metallic particles. The metallic particles may serve to reduce the formation of intermetallics on at least one of the first and second opposing surfaces upon the application of solder. As well as reducing the formation of intermetallics, the particles may also help with mechanical reinforcement of solder joints.

In one or more embodiments, the metallic particles may include Ni, Ag, Cu, rare earth metals, or a combination thereof. However, it will be appreciated that other particles may also be used to provide mechanical reinforcement such as Fe2O3, TiO2, and SiC particles or graphene flakes. A suitable diameter of the particles may be in the order of 40 to 100 microns.

In one or more embodiments, the semiconductor die may be arranged between the socket and the head wire with the source terminal facing the socket.

In one or more embodiments, the semiconductor die may be arranged between the socket and the head wire with the drain terminal facing the socket.

In one or more embodiments, the semiconductor die may be of substantially rectangular shape when viewed in plan. Other shapes are possible in other forms of the invention, including hexagonal, square, circular, as well as arbitrary shapes to which may be diced to control forces to or from particular points of the semiconductor die. For example, to reduce the interfacial forces between layers and external connections supported thereon

In one or more embodiments, the semiconductor die may include silicone, silicon carbide, gallium arsenide, gallium nitride, or a combination thereof. In other forms of the invention, the semiconductor substrate or wafer may be a silicon-based semiconductor substrate, or silicon carbide-based semiconductor substrate, or gallium arsenide-based semiconductor substrate or gallium nitride-based semiconductor substrate, for example.

In one or more embodiments, the semiconductor die may be packed in the two terminal press fit package with an electronic moulding compound. The moulding compound ma include a plastics material, for instance an acrylic or epoxide-based plastics material. The semiconductor die may be over moulded with a moulding compound, e.g. glass-epoxy material, to lead to a better adhesion between moulding compound and chip.

In one or more embodiments, the semiconductor die may be packed in the two terminal press fit package with an epoxy composition including an epoxy resin and a hardener.

### BRIEF DESCRIPTION OF DRAWINGS

The invention will now be described in further detail by reference to the accompanying drawings. It is to be understood that the particularity of the drawings does not superseded the generality of the preceding description of the invention.

FIG. 1 shows a cross sectional view of a rectifying device;

FIG. 2 shows a schematic view of a rectifying device;

FIG. 3a shows a cross sectional view of a semiconductor die;

FIG. 3b shows a plan view of a semiconductor die;

FIG. 3c shows a plan view of a semiconductor die;

FIG. 4 shows a cross sectional view of a semiconductor die with mechanical reinforcement of solder joints via a metal mesh;

FIG. 5 shows a cross sectional view of a semiconductor die with mechanical reinforcement of solder joints via nano-sized materials;

FIG. 6a shows an isometric view of a semiconductor die with mechanical reinforcement of solder joints via bumps or ridges;

FIG. 6b shows a plan view of a semiconductor die with mechanical reinforcement of solder joints via bumps or ridges;

FIG. 7a shows cross sectional view of a semiconductor die with mechanical reinforcement of solder joints via surface texturing; and

FIG. 7b shows a close-up plan view of a semiconductor die with mechanical reinforcement of solder joints via surface texturing.

### DETAILED DESCRIPTION

The invention is suitable for packaging in a press-fit packaging, and it will be convenient to describe the invention in relation to that exemplary, but non-limiting, application.

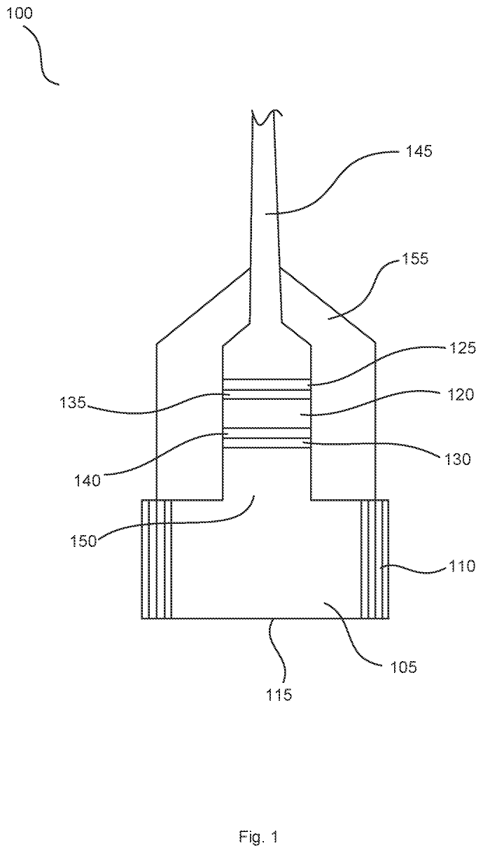

Referring firstly to FIG. 1, there is shown an illustration of an embodiment of a press-fit rectifying diode, as can be produced by a method according to the invention. This press-fit rectifying diode 100 has a socket 105 provided with a knurling 110, which can be pressed, for example, in a vehicle alternator system into a corresponding recess of a rectifier plate. The base 115 assumes at the same time a permanent thermal and electrical connection of the rectifier diode to the rectifier plate. The base 115 has a fastening region on which a monolithic semiconductor die 120, is fastened by a solder joint 125, 130.

Between the solder 125 and the semiconductor die 120, a metallised bonding layer 135 is provided. Between the solder 130 and the semiconductor die 120, a metallised bonding layer 140 is also provided. The metallised bonding layers 135 and 140 may be disposed on either side of the semiconductor die 120 by vacuum deposition or the like and those skilled in the art will recognise suitable conducting materials for providing the stated functions, for example, copper (Cu), copper alloys, iron-nickel alloys (for instance the so-called “Alloy 42”), aluminium (Al), silver (Ag), noble metals, palladium (Pd), gold (Au) and the like. The metallised bonding layers 135 and 140 may be different materials or the same material. That is, the first and second opposing surfaces of the monolithic semiconductor die 120 may each be copper, or for example, one side may be copper, and the other side may be aluminium or any combination thereof.

In one or more embodiments, the first and second terminals 145, 150 are each soldered to the respective solder joins 125, 130. It will be appreciated that in one or more embodiments the first or second terminals 145, 150 may comprise the socket 105 (or “can”) of the press fit package or a “head wire”.

In one or more embodiments, the monolithic semiconductor die 120 is packed in the two terminal press fit package with an electronic moulding compound or with an epoxy composition including an epoxy resin and a hardener 155. The electronic moulding compound or epoxy composition may be provided as a mechanical stress buffer.

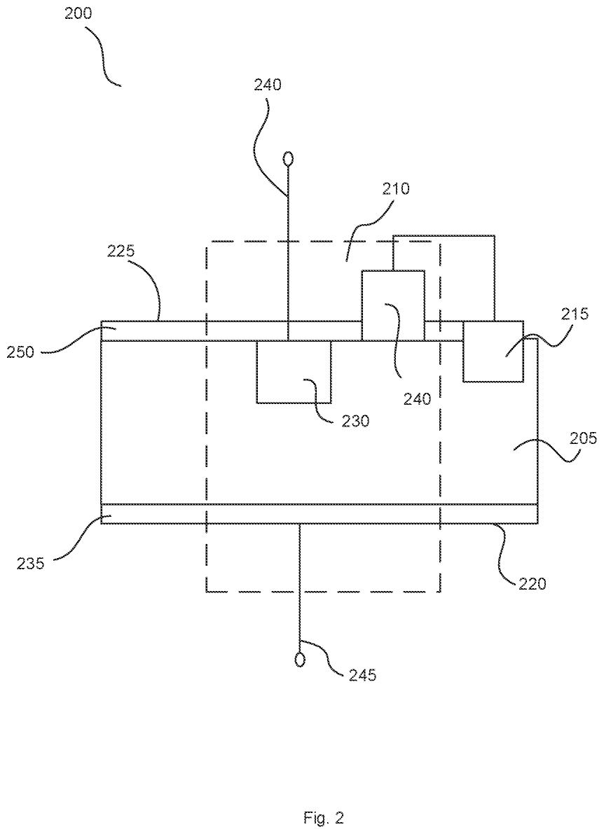

Referring to FIG. 2, there is shown an illustration of an embodiment of a rectifying device 200.

The rectifying device 200 includes a power transistor 210 and a gate 215 formed on a monolithic semiconductor die 205 having first and second opposing surfaces 220, 225. The power transistor 210 includes a source terminal 230, a drain terminal 235 and a gate terminal 240. In one or more embodiments, the gate terminal 240 is not an external terminal. A first terminal 240 (or input depending on the biasing) of the rectifying device 200 is coupled to the source terminal 230 of the power transistor 210. A second terminal 235 (or output depending on the biasing) of the rectifying device 200 is coupled to the drain terminal 235 of the power transistor 210. The gate terminal 240 of the rectifying device 200 is coupled to the gate control circuit 215. The coupling may be in a metal layer 250 of the semiconductor die 205 with no external bonding, as shown.

The gate control circuit 215 operable to control a gate voltage at the gate 240 of the power transistor 210 based on at least one parameter relating to at least one of a voltage and a current between the first terminal 240 and the second terminal 245. As will be appreciated the first and second terminals 240, 245 may be considered “inputs” or “outputs” depending on the biasing of the rectifying device 200. As will also be appreciated the terms source 230, drain 235 and gate 240 may also be referred to as emitter, collector and base, respectively.

Advantageously, forming the gate control circuit for controlling the gate of a power transistor and the power transistor on a common semiconductor die, no further external control or supply circuit may be needed to operate the rectifying device. Further, the rectifying device only requires two external terminals and may be packaged in a two-terminal housing, including the housing described with reference to FIG. 1. For example, a press-fit package commonly used for diode rectifiers, for example in automotive applications, may be used with the rectifier device of the present invention. A monolithic arrangement may lead to simplified construction and reduced costs, for example.

The rectifying device 200 is implemented on a single semiconductor die or semiconductor chip. For example, the power transistor 210 and the gate control circuit 215 are formed on or in the same semiconductor die 205. The semiconductor substrate or wafer may be a silicon-based semiconductor substrate, or silicon carbide-based semiconductor substrate, or gallium arsenide-based semiconductor substrate or gallium nitride-based semiconductor substrate, for example. Each side of the semiconductor die 205 is metallised 220, 225.

The semiconductor die 205, is of substantially rectangular shape when viewed in plan. However, other shapes are possible including hexagonal, square, circular, as well as arbitrary shapes to which may be diced to control forces to or from particular points of the semiconductor die 205. For example, to reduce the interfacial forces between layers and external connections supported thereon.

The rectifying device 200 may be used for rectifying an alternating signal e.g., for conversion of an alternating-current (AC) input into a direct-current (DC) output. For example, the rectifying device 200 may be connected to an alternator in a vehicle, such as a car, as part of an alternator circuit. As will be appreciated, a set of rectifiers (diode bridge) may be interconnected in a bridge circuit configuration that provides the same polarity of output for either polarity of input. When used in in this application the bridge rectifier may provide full-wave rectification from a two-wire AC input. A set of rectifying devices may be implemented on a common semiconductor die, for example.

The rectifying device 200 may be configured to receive an input alternating signal via its first terminal 240, for example. The rectifying device 200 may rectify the alternating signal. For example, the rectifying device 200 may be configured to produce a rectified output signal at the second terminal 245 of the rectifying device 200. In this manner, the power transistor 210 may be configured to allow either the positive or negative half of the AC signal to pass, while the other half is blocked. This may be achieved by alternatingly operating in a transistor on-state or a transistor off-state, e.g., by switching between a transistor on-state (conducting state) and a transistor off-state (blocking state), resulting in half-wave rectification of a single-phase supply, or the like.

As will be appreciated, depending on the type of alternating signal supply and the arrangement of the rectifier device, the output voltage may require additional smoothing to produce a uniform steady voltage. In these applications the output of the rectifier may be smoothed by an electronic filter, which may be a capacitor structure, or set of capacitor structures, possibly followed by a voltage regulator to produce a steady voltage.

The power transistor 210 used in the rectifying device 200 may be a three-terminal device. The “source or emitter terminal” may refer to a first terminal of the three-terminal device, for example. The “drain or collector terminal” may refer to a second terminal of the three-terminal device, for example. The “gate or base terminal” may refer to a third terminal of the three-terminal device, for example. Only two of the transistor terminals may be externally accessible from outside the device or from outside the common semiconductor die.

Depending on the application, the power transistor may be a field effect transistor, (e.g. a metal oxide semiconductor field effect transistor MOSFET) having a source terminal, a drain terminal and a gate terminal, for example, or an insulated gate bipolar transistor (IGBT) or a bipolar junction transistor (BJT) having an emitter terminal, a collector terminal and a base terminal, for example.

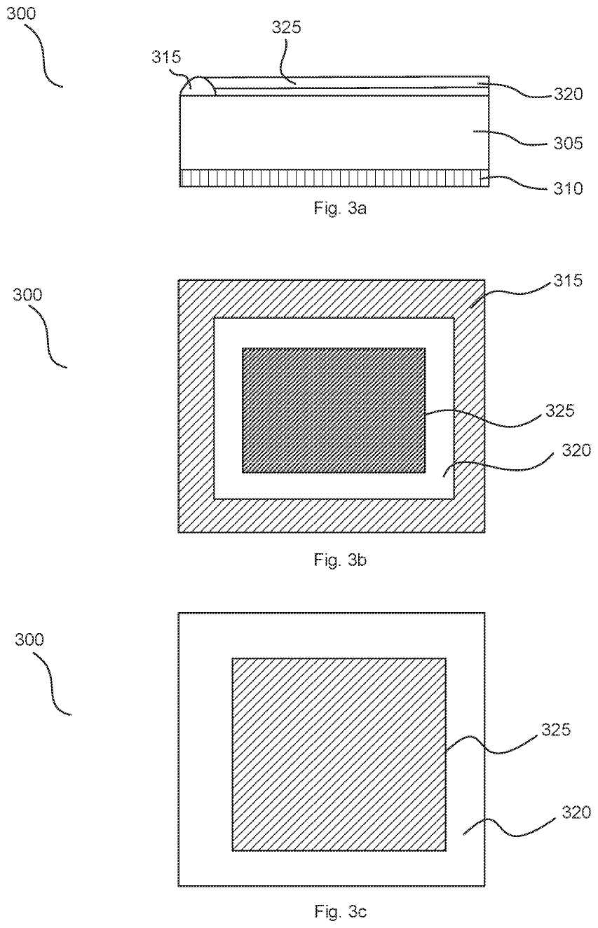

Referring to FIG. 3a, there is shown an illustration of an embodiment of a monolithic semiconductor die 300. As discussed with reference to FIG. 2, the rectifying device is implemented on a single semiconductor die or semiconductor chip 300. For example, the power transistor and the gate control circuit are formed on or in the same semiconductor die 300. The semiconductor substrate 305 or wafer may be a silicon-based (e.g., bulk silicone) semiconductor substrate, or silicon carbide-based semiconductor substrate, or gallium arsenide-based semiconductor substrate or gallium nitride-based semiconductor substrate, for example. Each side of the semiconductor die 300 is metallised 310, 320. Imide 315 is provided as a mechanical stress buffer and also acts as an electrical insulator and solder barrier.

In the embodiment shown, each side of semiconductor substrate 305 is metallised. Metal increases the mechanical strength of the structure and improves heat dissipation. The bottom layer 310 is coated in a layer of silver around 200 microns thick. The top layer 320 is coated in copper. The metal layers dissipated the high heat losses from the semiconductor via a press-fit packaging, for example. As will be appreciated a press-fit packaging, particularly when mounted in a rectifier plate, will provide thermal resistance. Furthermore, the semiconductor die 300 or chip may be cooled from both sides (e.g. from a die front side or a die back side) through the metal surfaces 310, 320.

The semiconductor die 300 includes a solderable front and back side with respectively at least one contact, for example a “head wire”, as described with reference to FIG. 1. The embodiment shown relates to a Cu—Si—Al Copper-Silicon-Aluminium rectifier arrangement. However, the invention is suitable for different metals e.g., Cu—Si—Cu Copper-Silicon-Copper, and the like.

In one or more embodiments, a nickel diffusion barrier 325 is deposited on at least part of the copper surface 320 for reducing the formation of intermetallics upon the application of solder. As will be appreciated, the formation of intermetallics may take place during reflow when the tin (Sn) in solder reacts with the copper substrate or layer. In Sn-rich solders on a Cu substrate, Cu6Sn5 (η) or Cu3Sn (ε) intermetallic layers may be formed at the solder/substrate interface leading to eventual dewetting, which may result in solder joint failure (because interfacial intermetallic compound layers are prone to crack initiation and failure and other degraded mechanical properties). Advantageously, nickel provides a very effective diffusion barrier, preventing copper from migrating to the surface and also helps to prevent copper-tin intermetallic formation in tin and tin-lead coated contacts. A suitable thickness of the nickel diffusing layer may be in the order of 40 to 100 microns.

It will be appreciated that there are several materials suitable for surface metallisation, including aluminium and gold and those skilled in the art will recognize suitable materials for providing the corresponding diffusion barriers, for example, NiVCr or TiNiV.

Referring to FIG. 3b, there is shown an illustration of an embodiment of a monolithic semiconductor die 300 in plan view, for example the monolithic semiconductor die 300 of FIG. 3a.

A nickel diffusion barrier 325 is deposited in a rectangle on copper surface 320 for reducing the formation of intermetallics upon the application of solder. The semiconductor die 300 is surrounded by imide 315 to provide a mechanical stress buffer and to act as a solder exclusion zone around the semiconductor die 300, in order to constrict solder flow. It will be appreciated that while a rectangle diffusion barrier is shown, other shapes are possible, for example square, circular, hexagonal or their combination.

Referring to FIG. 3c, there is shown an illustration of an alternative embodiment of a monolithic semiconductor die 300 in plan view.

A nickel diffusion barrier 325 is deposited across the entire copper surface 320 for reducing the formation of intermetallics upon the application of solder.

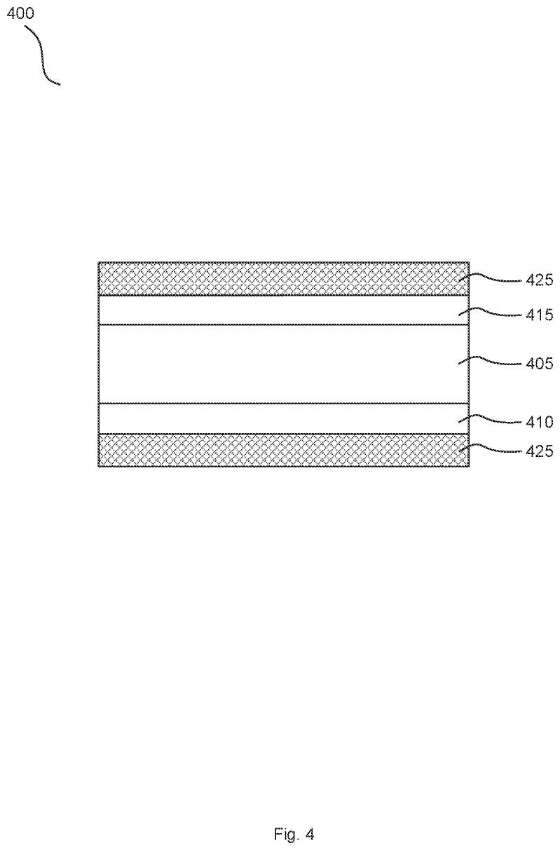

Referring to FIG. 4, there is shown an illustration of an embodiment of a monolithic semiconductor die 400, such as the semiconductor die discussed with reference to FIG. 2.

The semiconductor substrate 405 or wafer may be a silicon-based (e.g., bulk silicone) semiconductor substrate and is metallised on both sides 410, 415. In the embodiment shown, each surface 410 and 415 is copper and further includes a metallic mesh 425 (e.g., a metallic, braided, woven, or expanded mesh) disposed thereon for reducing the formation of intermetallics upon the application of solder. However, it will be appreciated that the metallic mesh 425 may only be disposed on one surface, for example the top surface 415.

It will be appreciated that there are several materials suitable for the mesh 425 material, including materials which may alter the chemical composition of widely-used lead-free Sn-based solder alloys and strengthen solder joints by adding or modifying the content of alloying elements such as Ag, Ni, Bi, In, Sb, or Ce. Alternatively, in other implementations, the mesh may comprise a high melting point nonmetallic material such as polymer having high thermal stability.

The mesh material 425 may be dimensioned to be of similar height to the solder bondline, for example 25 to 200 microns and arranged in a mesh liked pattern. For example, a mesh including interstitial spaces, where the solder melts during reflow soldering and where the mesh does not melt during reflow soldering. The interstitial spaces may be shaped as polygons such that the mesh is rectangular, triangular, etc. Alternatively, the interstitial spaces may be shaped as ellipses (e.g., the mesh may be circular).

The integration of the metallic mesh 425 may also stabilise the solder against mechanical and thermomechanical loading and to increase the thermal conductivity of the joint. Advantageously, stabilising the solder can also reduce a tilted head wire in manufacture and avoid the formation of “solder wedge”. Additionally, solder creep may be slowed thereby enhancing wetting. As will be appreciated by those skilled in the art, “solder wedge” may be considered an uneven solder bondline thickness between a surface (for example, surface 415) and another connection (for example, a head wire or other external connection) causing stress concentration at the thinner sections of the solder bond. Such an assembly is problematic as solder joint thickness is correlated with induced crack length after thermal cycling and can lead to premature failure and the like.

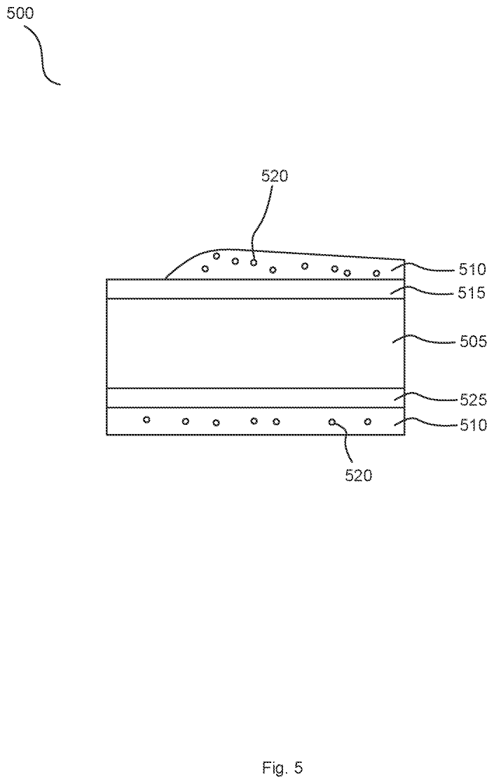

Referring to FIG. 5, there is shown an illustration of an embodiment of a monolithic semiconductor die 500, such as the semiconductor die discussed with reference to FIG. 2.

The semiconductor substrate 505 or wafer may be a silicon-based (e.g., bulk silicone) semiconductor substrate and is metallised on both sides 515, 525. In the embodiment shown, the die 500 is a Cu—Si—Cu Copper-Silicon-Copper 515, 505, 525 die 500 and further includes solder 510 containing metallic particles 520 disposed thereon for reducing the formation of intermetallics upon the application of solder 510.

In one or more embodiments, the die 500 is adapted to be soldered between the socket and the head wire of a press-fit package, for example the press-fit package discussed with reference to FIG. 1. As well as reducing the formation of intermetallics, the particles may also help with mechanical reinforcement of solder joints. The metallic particles may include Ni, Ag, Cu, rare earth metals, or a combination thereof. However, it will be appreciated that other particles may also be used to provide mechanical reinforcement such as Fe₂O₃, TiO₂, and SiC particles or graphene flakes. A suitable diameter of the particles may be in the order of 40 to 100 microns.

The integration of the metallic particles 520 may also stabilise the solder against mechanical and thermomechanical loading and to increase the thermal conductivity of the joint. Advantageously, stabilising the solder can also reduce a tilted head wire in manufacture and avoid the formation of solder wedge. Additionally, solder creep may be slowed thereby enhancing wetting.

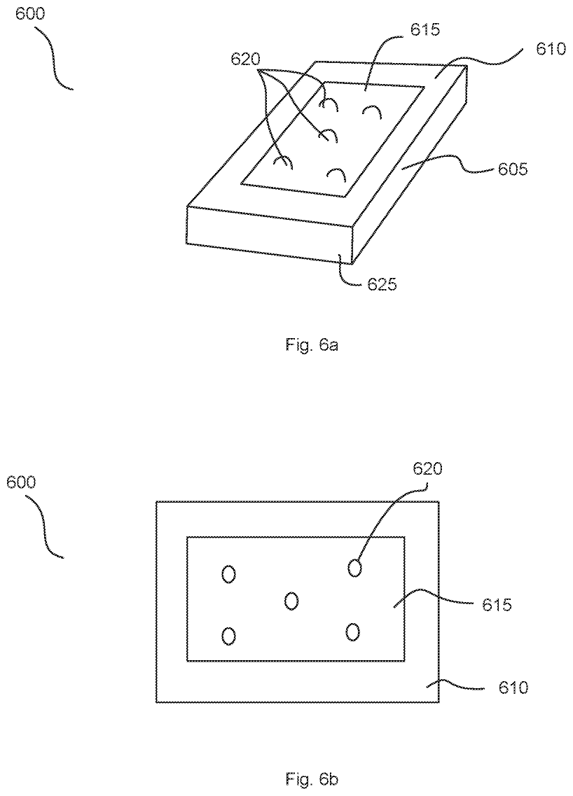

Referring to FIG. 6a, there is shown an illustration of an embodiment of a monolithic semiconductor die 600, such as the semiconductor die discussed with reference to FIG. 2.

The semiconductor substrate 605 or wafer may be a silicon-based is metallised on both sides 610, 625. In the embodiment shown, the die 600 is a Cu—Si—Cu Copper-Silicon-Copper 610, 605, 625 die 600 and further includes a plurality of structures 620 patterned for controlling solder flow to provide a consistent bondline to a head wire, for example.

In one or more embodiments, the structures 620 are semicircular bumps or ridges disposed on the copper surface 615. The structures are dimensioned to be of similar height to the solder bondline, for example 30 or 50 microns and arranged in a grid-like pattern. However, it will be appreciated that the structures 620 may be randomly or pseudo-randomly disposed on the copper surface 615. Additionally or alternatively, the plurality of structures 620 may include polymers, for example an imide or polymide resin coating selectively applied to the copper surface 615 which may be baked to form a bump or ridge. Alternatively, in other implementations, the ridges or bumps may be stamped in the copper surface 615.

Advantageously, providing a plurality of structures 620 patterned for controlling solder flow allows the soldering dwell time to be controlled while the solder is molten as this will dissolve more copper through liquid state diffusion. The structures 620 may also stabilise the solder against mechanical and thermomechanical loading and to increase the thermal conductivity of the joint.

FIG. 6b shows an illustration of the embodiment of the monolithic semiconductor die 600 described with reference to FIG. 6a but in plan view, and accordingly shares the same reference numbers.

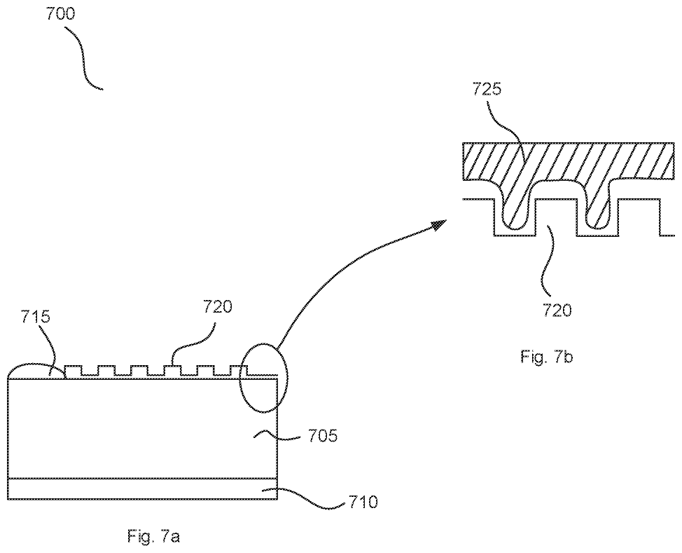

Referring to FIG. 7a, there is shown an illustration of an embodiment of a monolithic semiconductor die 700, such as the semiconductor die discussed with reference to FIG. 2.

The semiconductor substrate 705 or wafer may be silicon-based and is metallised on both sides 710, 720. In the embodiment shown, the die 700 is a CuSiCu Copper-Silicon-Copper 720, 705, 710 die 700. The surface 720 is textured for preventing the propagation of cracks that may form in intermetallics and solder upon the application of solder 725. The semiconductor die 700 is surrounded by imide 715 to provide a mechanical stress buffer.

In one or more embodiments, the surface 720 is formed with ridges or groves or the like instead of a smooth surface. The ridges or grooves are dimensioned to permit the admittance of solder 725. Advantageously, a rough surface may improve the mechanical properties of the joint due to the decreased resistance to shear along the interface. Alternatively, in other implementations, the ridges or grooves may be stamped or chemically etched in the copper surface 615.

It will be appreciated that the surface texturing 720 may also be used in combination with a Ni diffusion barrier. As described above, Ni provides an ideal diffusion barrier against Cu—Sn intermetallic growth when used as metallization above Cu substrate due to its slow rate of dissolution in molten Sn-rich solder, slow consumption of Ni through intermetallic growth, and slow rate of diffusion of Cu through Ni.

FIG. 7b shows a close up illustration of the embodiment of the monolithic semiconductor die 700 described with reference to FIG. 7a and accordingly shares the same reference numbers.

For the purposes of description herein, the terms “side”, “top”, “bottom”, “upside down”, “inverted” and derivatives thereof shall be related to the rectifying device of FIG. 1.

Where the terms “comprise”, “comprises”, “comprised” or “comprising” are used in this specification (including the claims) they are to be interpreted as specifying the presence of the stated features, integers, steps or components, but not precluding the presence of one or more other features, integers, steps or components, or group thereof.

While the invention has been described in conjunction with a limited number of embodiments, it will be appreciated by those skilled in the art that many alternative, modifications and variations in light of the foregoing description are possible. Accordingly, the present invention is intended to embrace all such alternative, modifications and variations as may fall within the spirit and scope of the invention as disclosed.

What is claimed is:

1. A rectifying device, comprising:
a semiconductor die having first and second opposing surfaces;
a first terminal and a second terminal;
a power transistor having a source terminal connected to one of the first terminal or the second terminal of the rectifying device, a drain terminal connected to the other one of the first terminal or the second terminal of the rectifying device and a gate;
a gate control circuit operable to control a gate voltage at the gate of the power transistor based on at least one parameter relating to at least one of a voltage and a current between the first terminal and the second terminal; and
a capacitor structure,
wherein the power transistor, the gate control circuit and the capacitor structure are arranged in the semiconductor die forming a monolithic structure and the first and second opposing surfaces are at least in part metallised.

2. The rectifying device of claim 1, wherein at least one of the first and second opposing surfaces is a solderable surface.

3. The rectifying device of claim 1, wherein at least one of the first and second opposing surfaces is a Cu surface.

4. The rectifying device of claim 3, wherein the Cu surface includes a Ni diffusion barrier deposited on at least part of the Cu surface for reducing the formation of intermetallics upon the application of solder.

5. The rectifying device of claim 3, wherein the Cu surface further includes a metallic mesh disposed thereon for reducing the formation of intermetallics upon the application of solder.

6. The rectifying device of claim 3, wherein the Cu surface is textured for preventing the propagation of cracks that may form in intermetallics and solder upon the application of solder.

7. The rectifying device of claim 3, wherein the Cu surface includes a plurality of structures patterned for controlling solder flow.

8. The rectifying device of claim 7, wherein the plurality of structures include metallic or polymer bumps disposed on the Cu surface.

9. The rectifying device of claim 1, wherein at least one of the first and second opposing surfaces is selected from the group consisting of: Ag, Au or Al.

10. The rectifying device of claim 1, wherein the semiconductor die is adapted to be packed in a two terminal press fit package having a socket and a head wire.

11. The rectifying device of claim 10, wherein the semiconductor die is soldered between the socket and the head wire.

12. The rectifying device of claim 11, wherein the semiconductor die is soldered between the socket and the head wire with a solder containing metallic particles.

13. The rectifying device of claim 12, wherein the metallic particles serve to reduce the formation of intermetallics on at least one of the first and second opposing surfaces upon the application of solder.

14. The rectifying device of claim 13, wherein the metallic particles comprise Ni, Ag, Cu, rare earth metals, or a combination thereof.

15. The rectifying device of claim 10, wherein the semiconductor die is arranged between the socket and the head wire with the source terminal facing the socket.

16. The rectifying device of claim 10, wherein the semiconductor die is arranged between the socket and the head wire with the drain terminal facing the socket.

17. The rectifying device of claim 1, wherein the semiconductor die is of substantially rectangular shape when viewed in plan.

18. The rectifying device of claim 1, wherein the semiconductor die comprises silicone, silicon carbide, gallium arsenide, gallium nitride, or a combination thereof.

19. The rectifying device of claim 10, wherein the semiconductor die is packed in the two terminal press fit package with an electronic moulding compound.

20. The rectifying device of claim 10, wherein the semiconductor die is packed in the two terminal press fit package with an epoxy composition including an epoxy resin and a hardener.
